(19) United States
(12) Patent Application Publication
(10) Pub. No.: US 2011/0299230 A1
(43) Pub. Date: Dec. 8, 2011

(54) Relative movement urging device and electronic device using the relative movement urging device

(76) Inventor: Noriaki Kubota, Tokyo (JP)

(21) Appl. No.: 12/791,977

(22) Filed: Jun. 2, 2010

(51) Int. Cl. H05K 5/02; F16H 21/44

(52) U.S. Cl. 361/679.01; 74/99 R; 74/100.1

(57) ABSTRACT

The relative movement urging device urges the relative movement of the first member and the second member which are connected in a relatively movable manner. The relative movement urging device includes a first connecting member connected to the first member, a second connecting member which is movable in the departing direction with respect to the first connecting member and is connected to the second member, and a guide member to which the first connecting member and the second connecting member are slidably connected with urging in the mutually departing direction. The guide member includes a first guide section which guides the slide of the first connecting member and a second guide section which is in parallel with the side of the first guide section to guide the slide of the second connecting member. The guide member is formed in a shape in which each basal end of the first guide section and the second guide section becomes a protruded basal end which extends backward over the distal end of the other guide section.

### BACKGROUND OF THE INVENTION

1. Field of the Invention

The present invention relates to a relative movement urging device and an electronic device using the relative movement urging device.

2. Description of the Related Art

A conventional folding cellular phone has an operation section on which numeric keys and function keys are arranged, on the upper surface of a main unit section, which is on the lower side, and a display section such as a liquid crystal panel, on which predetermined display is provided through key operations on the operation section, on the covered surface side (overlaid side) of an overlaying section, which is on the upper side. The main unit section and the overlaying section are connected by a hinge device to allow the main unit section and the overlaying section to be overlaid in a folding manner, thereby providing a folded closed state, in which the operation section is concealed by the overlaying section. The overlaying section is pivoted in a lifting/closing manner to be reversed by the hinge device, thereby switching the folded closed state into an open state, in which the operation section and the display section are exposed.

In a conventional electronic device in which the operation section of the main unit section is covered with the overlaying section which thus pivots in a lifting/closing manner, the main unit section and the overlaying section are folded to be overlaid, achieving compactification. However, the overlaid state which conceals the operation section also conceals the display section, limiting use in the compactified state. In addition, when operating the operation section, the heavy overlaying section provided with the display section has to be lifted and pivoted to be reversed, providing another drawback in that it has difficulty in the opening/closing actions (the opening action, in particular).

When the opening/closing actions are achieved by sliding the overlaying section backward and forward along the overlaying surface, not by pivot in a lifting/closing manner, the display section can be provided on the upper side of the overlaying surface. In this case, even in the overlaid state when being not in use or when key operations are unnecessary, in other words, even in the compact state in which the overlaying section provided with the display section is overlaid on the main unit section to conceal the operation section, the display section can be provided on the upper side, allowing the display section to be viewed or functioned. Switching of the overlaid and compactified state into the state in which the operation section is exposed can be achieved by sliding the overlaying section backward and forward along the overlaying surface. Electronic devices such as a cellular phone and a mobile device are thereby provided, which allows the opening action to be performed very easily, increases the range of use as a device, and allows the opening/closing actions to be performed easily.

When an electronic device is constructed to be the slide opening/closing type, a slide device is used for connecting the main unit section and the overlaying section to slidably connected. In a preferable example, when the operation section of the main unit section is caused to slide from the overlaid closed position in which it is concealed by the overlaying section, to a predetermined slide position in which the overlaying section is slid forward, the overlaying section is automatically slid to a slide open position in which the overlaying section allows the operation section to be exposed.

There is a patent document disclosing a conventional relative movement urging device. This conventional relative movement urging device provides a slide structure (a relative movement structure) for sliding the overlaying section along the overlaying surface with respect to the main unit section with an urging force. The conventional example includes a first connecting member pivotally connected to the main unit section, a second connecting member which is slidably connected to the first connecting member in the longitudinal direction and is pivotally connected to the overlaying section, and a guide member to which the first connecting member and the second connecting member are slidably connected with urging in the mutually departing direction.

This conventional example produces backward urging which slides the overlaying section backward until the overlaying section is slid with respect to the main unit section by a predetermined length. When the overlaying section is slid with respect to the main unit section by the predetermined length, it produces, on the contrary, forward urging which slides the overlaying section forward. Urging action for slidingly urging the overlaying section with respect to the main unit section is thus achieved.
[Patent Document] Korean Utility Model Registration No. 20-0400694

### SUMMARY OF THE INVENTION

An object of the present invention is to provide a relative movement urging device which produces an unprecedented effect and an electronic device using the relative movement urging device.

An aspect of the present invention is a relative movement urging device for urging the relative movement of a first member and a second member which are connected in a relatively movable manner including: a first connecting member connected to the first member; a second connecting member which is movable in the departing direction with respect to the first connecting member and is connected to the second member; and a guide member to which the first connecting member and the second connecting member are slidably connected with urging in the mutually departing direction. The guide member includes a first guide section which guides the slide of the first connecting member and a second guide section which is in parallel with the side of the first guide section to guide the slide of the second connecting member. The guide member is formed in a shape in which each basal end of the first guide section and the second guide section becomes a protruded basal end which extends backward over the distal end of the other guide section.

Another aspect of the present invention is a relative movement urging device for urging the relative movement of a first member and a second member which are connected in a relatively movable manner including: a first connecting member connected to the first member; a second connecting member which is movable in the departing direction with respect to the first connecting member and is connected to the second member; and a guide member to which the first connecting member 4 and the second connecting member are slidably connected with urging in the mutually departing direction. The guide member includes a first guide section which guides the sliding of the first connecting member and a second guide section which is in parallel with the side of the first guide section to guide the slide of the second connecting member. The guide member is formed in a shape in which each basal end of the first guide section and the second guide section becomes a protruded basal end which extends backward over the distal end of the other guide section. Falling prevention sections are provided for supporting and preventing the falling of the first connecting member and the second connecting member which slide in the mutually departing direction while protruding from the distal ends of the first guide section and the second guide section, respectively, inside the protruded basal ends of the first guide section and the second guide section, respectively.

The first guide section and the second guide section having the same or substantially the same length are arranged in parallel with the distal end parts thereof connected, not with the basal end parts thereof connected in the facing side parts, or the inner side parts thereof. Another aspect of the present invention is the relative movement urging device, wherein the guide member is formed in a shape in which each basal end of the first guide section and the second guide section is a protruded basal end which extends backward over the distal end of the other guide section.

Another aspect of the present invention is the relative movement urging device, wherein the guide member includes a first hollow guide section having guide holes in the internal longitudinal direction and a second hollow guide section which is in parallel with the side of the first guide section and has guide holes in the internal longitudinal direction, which are formed integrally. The first connecting member and the second connecting member are provided with long slide sections which are slidably inserted into the guide holes which open at the distal ends of the first guide section and the second guide section, respectively. The slide sections are provided with disconnection preventive engagement sections which are engaged with engagement sections provided in the guide holes in a disconnection preventive manner when the slide sections are inserted into the distal end openings of the guide holes.

The slide sections are slidably inserted into the guide holes against the backward urging of springs fit on the slide sections. Another aspect of the present invention is the relative movement urging device, wherein the backward urging of the springs is an urging force for urging the first connecting member and the second connecting member in the mutually departing direction.

The first connecting member is connected to the first member and the second connecting member is connected to the second member, and until the second member is relatively moved with respect to the first member by a predetermined movement range, backward urging is produced for relatively moving the second member in the backward direction. Another aspect of the present invention is the relative movement urging device, wherein when the second member is relatively moved with respect to the first member by the predetermined movement range, forward urging is, on the contrary, produced for relatively moving the second member in the forward direction.

Another aspect of the present invention is an electonric device, wherein a relative movement structure to which the first member arranging an operation section or the like and the second member arranging a display section or the like are connected in a relatively movable manner is provided with the relative movement urging device.

Another aspect of the present invention is an electronic device, wherein a relative movement structure to which the first member arranging an operation section or the like and the second member which is overlaid on the first member and arranges a display section or the like are connected slidably in the overlaying surface direction is provided with the relative movement urging device.

Another aspect of the present invention is an electronic device, wherein a relative movement structure to which the first member arranging an operation section or the like and the second member which is overlaid on the first member and arranges a display section or the like are relatively pivotally connected substantially in parallel with the overlaying surface is provided with the relative movement urging device.

According to the present invention described above, as compared to the above-described conventional example, the pitch between the first connecting member and the second connecting member can be reduced to achieve the compactification of the relative movement urging device itself easily and surely. The revolutionary relative movement urging device produces an unprecedented effect in that it furthermore achieves the compactification of an electric device providing the relative movement urging device.

The revolutionary relative movement urging device produces an unprecedented effect in that favorable slide condition can be achieved and the durability of the first connecting member and the second connecting member can be remarkably improved by surely preventing the falling of the first connecting member and the second connecting member.

The revolutionary relative movement urging device produces an unprecedented effect in that it can be low in cost and is excellent in mass productivity because of its simple structure. Furthermore, the revolutionary relative movement urging device produces an unprecedented effect in that its durability can be improved further. The revolutionary relative movement urging device produces an unprecedented effect in that further compactification can be achieved because of its efficient structure. The relative movement urging device is therefore provided with excellent practicality.

An electronic device using the revolutionary relative movement urging device with excellent practicality which produces above-described effects can be provided.

### BRIEF DESCRIPTION OF THE DRAWINGS

FIG. 1 is an explanatory view of a use state of the present embodiment;

FIG. 2 is a perspective view of the present embodiment;

FIG. 3 is an elevation view of the present embodiment;

FIG. 4 is an exploded perspective view of the present embodiment;

FIG. 5 is a plan view of the present embodiment;

FIG. 6 is a bottom view of the present embodiment;

FIG. 7 is a cross-sectional view along a line A-A of FIG. 5;

FIG. 8 is an end surfaceview of the present embodiment;

FIG. 9 is a perspective view of the main part of the present embodiment;

FIG. 10 is an end view of the main part of the present embodiment;

FIG. 11 is a perspective view of the main part of the present embodiment;

FIG. 12 is a cross-sectional view of the main part of the present embodiment;

FIG. 13 is an explanatory view of the main part of the present embodiment;

FIG. 14 is an operational description diagram of the present embodiment;

FIG. 15 is an operational description diagram of the present embodiment;

FIG. 16 is an operational description diagram of the present embodiment;

FIG. 17 is a perspective view of another example of use of the relative movement urging device of the present embodiment.

FIG. 18 is a perspective view of another example of use of the relative movement urging device of the present embodiment;

FIG. 19 is a perspective view of another example of use of the relative movement urging device of the present embodiment;

FIG. 20 is a perspective view of another example of use of the relative movement urging device of the present embodiment;

FIG. 21 is a plan view of another example of use of the relative movement urging device of the present embodiment;

FIG. 22 is a plan view of another example of use of the relative movement urging device of the present embodiment; and

FIG. 23 is a plan view of another example of use of the relative movement urging device of the present embodiment.

### DETAILED DESCRIPTION OF THE PREFERRED EMBODIMENTS

An exemplary embodiment of the present invention will be described with reference to the drawings.

When the device is provided in the connecting part (a relative movement structure) between a first member 1 and a second member 2 connected in a relatively movable manner, it can provide a biasing force to the relative movement between the first member 1 and the second member 2.

Specifically, the device is provided with the function of urging a first connecting member 4 and a second connecting member 6 in the departing direction, and when it is provided, for example, in a slide structure (the relative movement structure) which slides the second member 2 which is overlaid on the first member 1 along an overlaying surface, when the first connecting member 4 is connected to the first member 1, while the second connecting member 6 is connected to the second member 2, urging action for slidingly the second member with respect to the first member 1 is achieved, in which backward urging is produced which slides the second member 2 backward until the second member 2 is slid with respect to the first member 1 by a predetermined length, and forward urging is, on the contrary, produced which slides it forward when the slide with the predetermined length is achieved.

The relative movement urging device includes the first connecting member 4 connected to the first member, the second connecting member 6 which is movable in the departing direction with respect to the first connecting member 4 and is connected to the second member 2, and a guide member 7 to which the first connecting member 4 and the second connecting member 6 are slidably connected with urging in the mutually departing direction. The guide member 7 inculdes a first guide section 8 which guides the slide of the first connecting member 4 and a second guide section 9 which is in parallel with the side of the first guide section 8 to guide the slide of the second connecting member 6. The guide member 7 is formed in a shape in which each basal end 8B, 9B of the first guide section 8 and the second guide section 9 becomes a protruded basal end 8B, 9B which extends backward over the distal end 8A, 9A of the other guide section. The structure, as compared to the above-described conventional example, can achieve the compactification of the relative movement urging device itself, and furthermore, can surely achieve the compactification of a part in which the relative movement urging device is provided.

When the relative movement urging device of the present invention and the relative movement urging device of the conventional example are compared to each other under the conditions that the first guide section 8 and the second guide section 9 are the same in length, the first connecting member and the second connecting member 6 for sliding the first guide section 8 and the second guide section 9 are the same in length, and the amounts of slide of the first connecting member 4 and the second connecting member 6 with respect to the first guide section 8 and the second guide section 9 are the same, the present invention can reduce the pitch between the distal ends of the first connecting member 4 and the second connecting member 6 as compared to the conventional example.

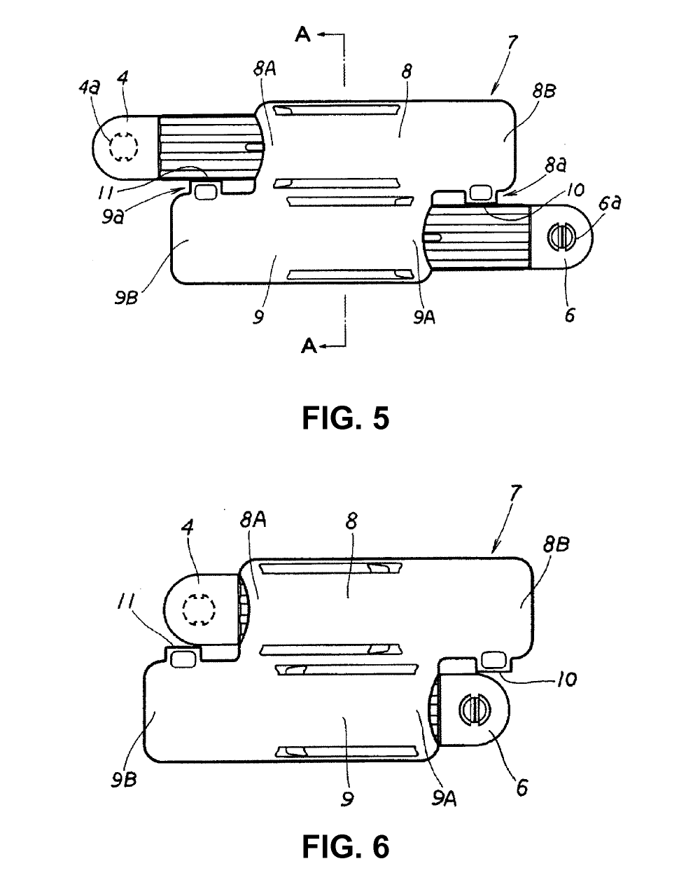

This is because the guide member 7 is formed in a shape in which each basal end 8B, 9B of the first guide section 8 and the second guide section 9 becomes a protruded basal end 8B, 9B which extends backward over the distal end 8A, 9A of the other guide section. In other words, the guide member 7 in the plan view is not a mere rectangular in shape as in the conventional example, but as shown in FIG. 5, the first guide section 8 and the second guide section 9 are arranged in parallel in which they are mutually backslid to be displaced backward and forward. The pitch between the tips of the first connecting member 4 and the second connecting member 6 can be thereby reduced without reducing the length of the first connecting member 4 and the second connecting member 6.

The compactification of the relative movement urging device itself can be therefore achieved, and furthermore, the compactification of a part in which the relative movement urging device can be surely achieved.

When falling prevention sections 10, 11 are provided for preventing the falling of the first connecting member 4 and the second connecting member 6 which slide in the mutually departing direction while protruding from the distal ends 8A, 9A of the first guide section 8 and the second guide section 9, respectively, inside the protrude basal ends 8B, 9B of the first guide section 8 and the second guide section 9, respectively, the structure can remarkably improve the performance and durability of the relative movement urging device without using any special structure.

More specifically, when the first connecting member 4 and the second connecting member 6 are slid with respect to the first guide section 8 and the second guide section 9 in the departing direction, in other words, when the amount of protrusion of each connecting member with respect to each guide section becomes large, a load associated with the slide of the first member 1 and the second member 2 acts on the first connecting member 4 and the second connecting member 6, and they are subjected to falling. The invention according to another exemplary embodiment, using the protruded basal ends 8B, 9B of the first guide section 8 and the second guide section 9 produced when the compactification of the relative movement urging device is achieved, can surely support and prevent the falling of the first connecting member 4 and the second connecting member 6 by the falling prevention sections 10, 11 provided inside the protruded basal ends 8B, 9B, and thereby can remarkably improve durability as compared to a structure which does not have any member which support the first connecting member 4 and the second connecting member 6 which slide while protruding from the first guide section 8 and the second guide section 9 like the above-described conventional example. In addition, the extremely efficient structure using the structure achieving compactification provides cost reduction and excellent mass productivity.

The present embodiment is obtained by applying the present invention to a cellular phone which can achieve overlaying compactification, and includes an operation section having keyboard functions on which numeric keys and function keys are arranged is provided on the upper side of the first member 1 (the main unit section 1), which includes electronic components such as a power supply in a casing and is a vertically long thick-plate shape and the second member 2 (the overlaying section 2), which is overlaid on the main unit section 1 to cover the operation section, is substantially the same shape, or a vertically long thick-plate shape, and is connected to the main unit section 1 through a slide structure (a relative movement structure 3) slidably in substantially the horizontal, longitudinal direction.

The upper side of the overlaying section 2 is provided with a display section such as a liquid crystal panel which is vertically long when it is overlaid and closed, in which predetermined display is provided by a preset screen, an operation on the operation section, an incoming call, or the like, and an image in landscape mode such as TV and DVD acquired through receiving it can be displayed.

The main unit section 1 and the overlaying section 2 are connected through the slide structure 3. The overlaying section 2 can be slidably opened/closed with respect to the main unit section 1. The overlaying section 2 slides between the overlaid closed position in which the operation section of the main unit section 1 is concealed by the overlaying section 2 and the slide open position in which the overlaying section 2 is slid in the longitudinal direction to be displaced, allowing the operation section to be exposed.

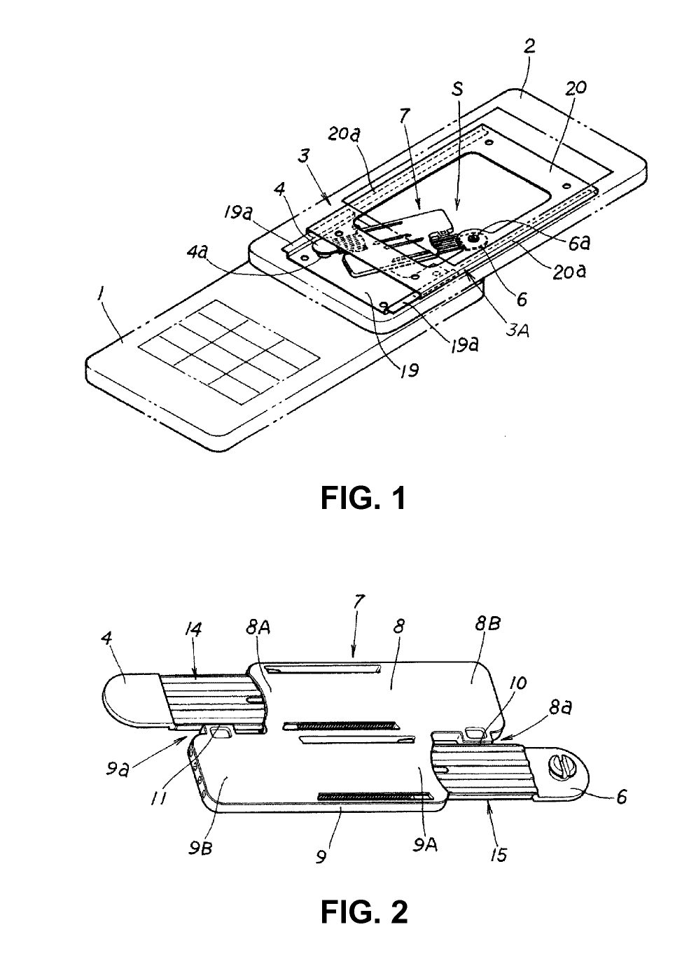

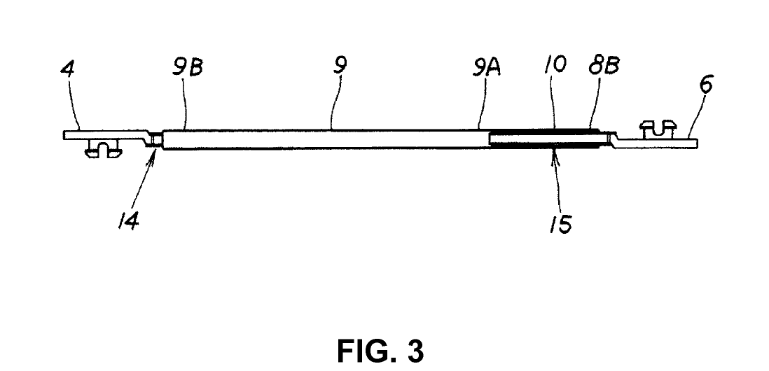

First, the slide structure 3 of the present embodiment will be described. The slide structure 3 connects the first member 1 (the main unit section 1) and the second member 2 (the overlaying section 2) which is overlaid on the first member 1 (the main unit section 1) slidably in the longitudinal direction. As shown in FIG. 1, guide piece sections 19a are formed by bending on the both sides of a plate-shaped guide member 19 as a part of the main unit section 1. A plate-shaped slide member 20 having slide piece sections 20a which are slidably engaged with the guide piece sections 19a as guides are provided as a part of the overlaying section 2.

In the present embodiment, therefore, the overlaying section 2 is slidable with respect to the main unit section 1 by sliding the slide member 20 with respect to the guide member 19, and in addition, the slide structure 3 between the main unit section 1 and the overlaying section 2 is provided with the relative movement urging device S.

The relative movement urging device S includes the first connecting member 4 connected to the main unit section 1, the second connecting member 6 which is movable in the departing direction with respect to the first connecting member 4 and is connected to the overlaying section 2, and the guide member 7 to which the first connecting member 4 and the second connecting member 6 are slidably connected with urging in the mutually departing direction (the backward and forward, opposite direction).

Specifically, the relative movement urging device S has a movable main unit including the first connecting member 4 pivotally connected to the main unit section 1 (a guide member 19), the second connecting member 6 pivotally connected to the overlaying section 2 (a slide member 20), and the guide member to which the first connecting member 4 and the second connecting member 6 are slidably connected in the mutually departing direction. Urging members 18 for slidingly urging the first connecting member 4 and the guide member 7 in the departing direction are provided between the first connecting member 4 and the guide member 7, while urging members 18 for slidingly urging the second connecting member 6 and the guide member 7 in the mutually departing direction are provided between the second connecting member 6 and the guide member 7, thereby providing the movable main unit with an urging mechanism for urging the first connecting member 4 and the second connecting member 6 in the departing direction.

The guide member 7 includes the first guide section 8 and the second guide section 9 which is in parallel with the first guide section 8 to guide the slide of the second connecting member 6.

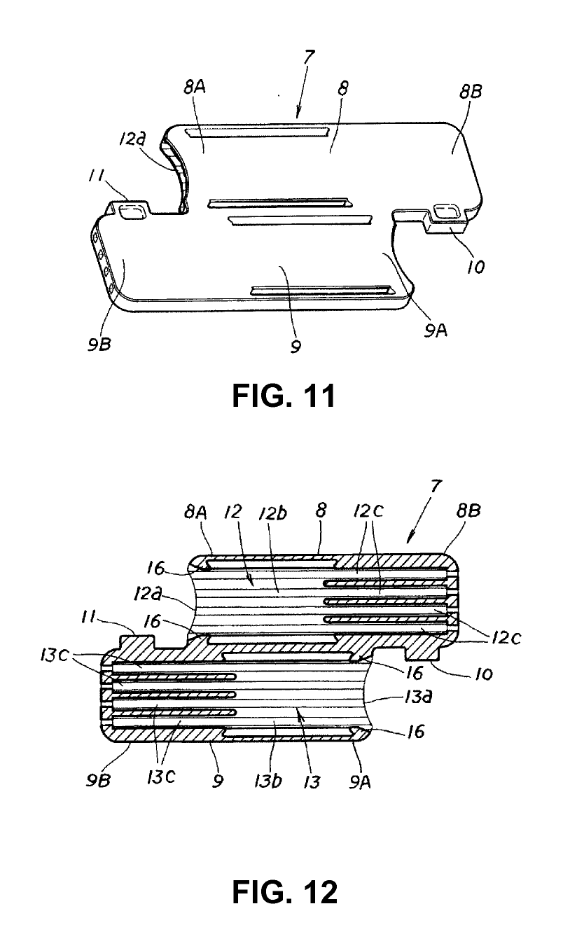

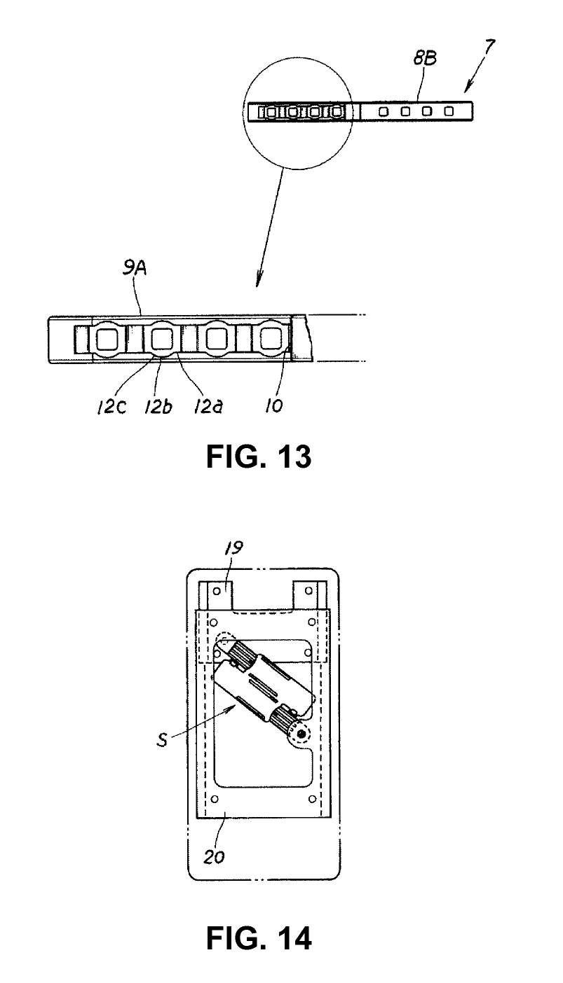

Specifically, the guide member 7 is, as shown in FIGS. 11, 12, 13, formed of an appropriate synthetic resin material, and is a flat-plate-shaped case structure, in which the first hollow guide section 8 having guide holes 12 in the internal longitudinal direction and the second hollow guide section 9 which is in parallel with the side of the first guide section 8 and has guide holes 13 in the internal longitudinal direction are formed integrally.

Into the guide holes 12, 13, slide sections 14, 15 of the first connecting member 4 and the second connecting member 6, which will be described later, are slidably inserted, and the guide holes 12, 13 include parts 12b, 13b to which the slide plate sections 14a, 15a constituting the slide sections 14, 15 are slidably inserted and parts 12c, 13c to which slide shaft sections 14b, 15b constituting the slide sections 14, 15 are slidably inserted.

The guide holes 12, 13 open at the distal ends of the first guide section 8 and the second guide section 9 in the exactly opposite direction. The distal end openings 12a, 13a are provided with engagement sections 16 with which disconnection preventive engagement sections 17 provided in the slide sections 14, 15 provided in the first connecting member 4 and the second connecting member 6, respectively, are engaged, which will be described later.

The guide member 7 is formed in a shape in which each basal end 8B, 9B of the first guide section 8 and the second guide section 9 becomes a protruded basal end 8B, 9B which extends backward over the distal end 8A, 9A of the other guide section.

Specifically, the guide member 7 is formed in a shape in which each basal end 8B, 9B of the first guide section 8 and the second guide section 9 becomes the protruded basal end 8B, 9B, which extends backward over the distal end 8A, 9A of the other guide section by allowing the first guide section 8 and the second guide section 9 having the same or substantially the same length to be arranged in parallel, with the distal end parts thereof connected, not with the basal end parts thereof connected in the facing side parts 8a, 9a, or the inner side parts thereof.

The guide member 7 in the plan view is, therefore, not a mere rectangular in shape as in the conventional example, but as shown in FIG. 5, the first guide section 8 and the second guide section 9 are arranged in parallel in which they are mutually backslid to be displaced backward and forward. The pitch between the tips (pivotally connecting sections 4a, 6a) of the first connecting member 4 and the second connecting member 6 can be thereby reduced without reducing the length of the first connecting member 4 and the second connecting member 6.

The guide member 7 is provided with falling prevention sections 10, 11 for supporting and preventing the falling of the first connecting member 4 and the second connecting member 6, which slide in the mutually departing direction, while protruding from the distal ends 8A, 9A of the first guide section 8 and the second guide section 9, respectively, inside the protruded basal ends 8B, 9B of the first guide section 8 and the second guide section 9, respectively.

The falling prevention sections 10, 11 are formed by providing protrusions inside the protruded basal ends 8B, 9B of the first guide section 8 and the second guide section 9, respectively, and support the sides of the first connecting member 4 and the second connecting member 6 when the first connecting member 4 and the second connecting member 6 slide and prevent them from falling.

In the present embodiment, the first guide section 8 and the second guide section 9 are formed integrally to constitute the guide member 7, but they may be formed separately. In this case, the first guide section 8 and the second guide section 9 are connected in parallel, while adjusting the protruding amounts of the protruded basal ends 8B, 9B of the first guide section 8 and the second guide section 9, respectively.

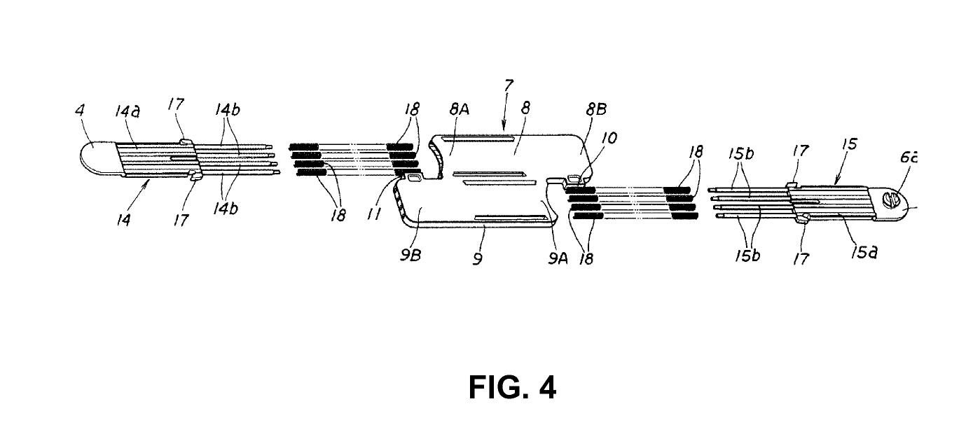

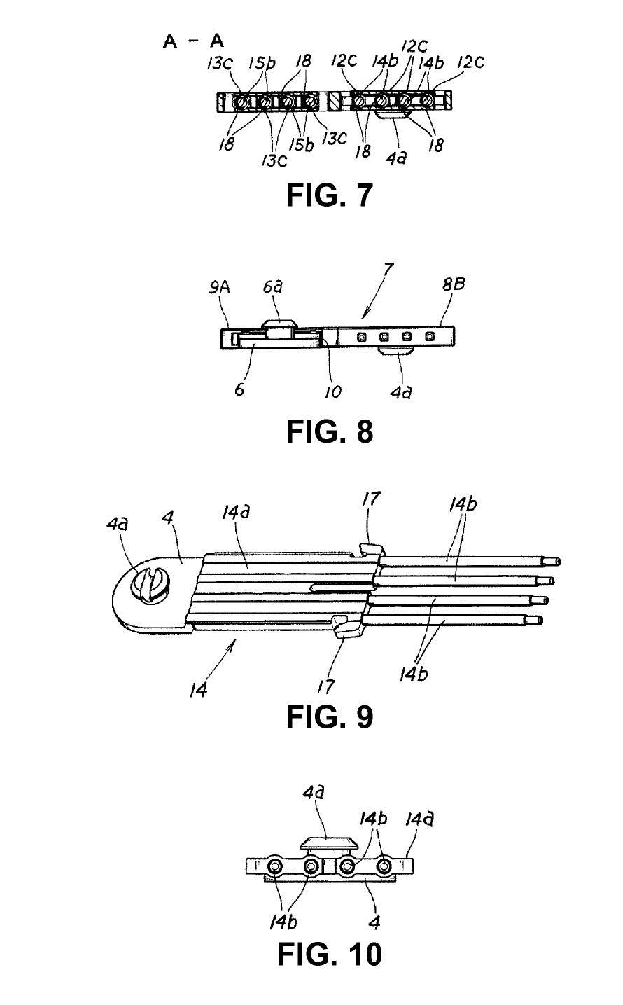

The first connecting member 4 and the second connecting member 6 are, as shown in FIGS. 4 to 10, formed integrally of an appropriate synthetic resin member. On their surfaces, the pivotally connecting sections 4a, 6a which are pivotally connected to the main unit section 1 (the guide member 19) and the overlaying section 2 (the slide member 20), respectively, are provided.

The first connecting member 4 and the second connecting member 6 are provided with the long slide sections 14, 15 which are slidably inserted into the guide holes provided in the first guide section 8 and the second guide section 9, respectively.

The slide sections 14, 15 include the slide plate sections 14a, 15a and a plurality of (four) slide shaft sections 14b, 15b protruding in parallel from the ends of the slide plate sections 14a, 15a, and are slidably inserted into the distal end openings 12a, 13a which open in the distal ends 8A, 9A of the first guide section 8 and the second guide section 9, respectively.

On the both parts of the tips of the slide plate sections 14a, 15a of the slide sections 14, 15, disconnection preventive engagement sections 17 are provided which are engaged with the engagement sections 16 provided in the distal end openings 12a, 13a of the guide holes 12, 13, respectively.

The disconnection preventive engagement sections 17 elastically deform inwardly. When the slide sections 14, 15 are inserted into the guide holes 12, 13, the both disconnection preventive engagement sections 17 deform inwardly at the positions at which the engagement sections 16 are provided, and then restore outwardly, thereby allowing them to be engaged with the engagement sections 16 in a disconnection preventive manner.

When the slide sections 14, 15 are inserted into the guide holes 12, 13, anti-contraction springs 18 (coil springs) are fit onto the slide sections 14, 15 (the slide shaft sections 14b 15b), and one ends of the coil springs 18 are in contact with the tips of the slide plate sections 14a, 15a, while the other ends thereof are in contact with the basal ends of the guide holes 12, 13.

By inserting the slide sections 14, 15 into the guide holes 12, 13, with the coil springs 18 fit thereon, to be engaged in a disconnection preventive manner, therefore, the first connecting member 4 and the second connecting member 6 are slidably connected to the guide member 7 (the first guide section 8 and the second guide section 9) in the mutually departing direction, in which the first connecting member 4 and the second connecting member 6 are constantly urged in the mutually departing direction (the tip direction) through urging by the coil springs 18, and the first connecting member 4 and the second connecting member 6 can move in the approaching direction against the urging in the departing direction. The urging force for urging the first connecting member 4 and the second connecting member 6 in the mutually departing direction which is produced when the first connecting member 4 and the second connecting member 6 move in the approaching direction is a relative movement urging force which urges the relative movement of the overlaying section 2 with respect to the main unit section 1, when the slide structure 3 is provided with the relative movement urging device S.

The number of the slide sections 14, 15 (the slide shaft sections 14b, 15b) and the number of the coil springs 18 which are fit on the slide sections 14, 15 (the slide shaft sections 14b, 15b) are appropriately changed, thereby adjusting the urging force and the amount of stroke appropriately.

As described above, when the movable main unit including the first connecting member 4, the second connecting member 6, and the guide member 7 is contracted by moving the pivotally connecting section 4a of the first connecting member 4 and the pivotally connecting section 6a of the second connecting member 6 in the approaching direction, anti-contraction urging is produced by the coil springs 18, and the anti-contraction urging is the urging force for urging the first connecting member 4 and the second connecting member 6 in the mutually departing direction.

When the slide structure 3 for the main unit section 1 and the overlaying section 2 is provided with the relative movement urging device S having the above-described structure, the pivotally connecting section 4a of the first connecting member 4 is pivotally connected to the main unit section 1 (the guide member 19), while the pivotally connecting section 6a of the second connecting member 6 is pivotally connected to the overlaying section 2 (the slide member 20).

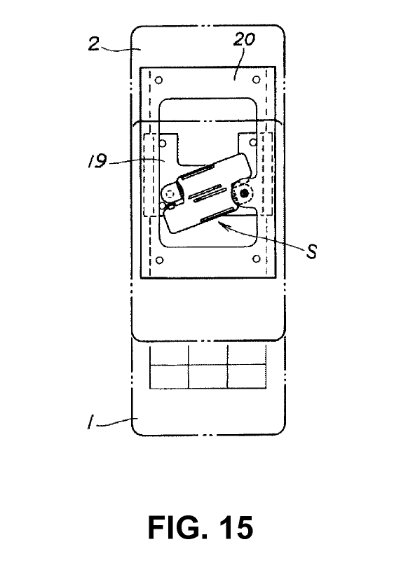

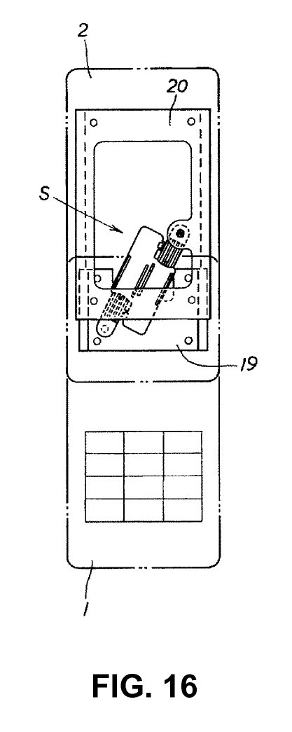

In the above state, until the overlaying section 2 is slid with respect to the main unit section 1 by a predetermined length, backward urging which slides the overlaying section 2 backward to the overlaid closed position automatically is produced. When the overlaying section 2 is slid by the predetermined length, forward urging is, on the contrary, produced which slides it forward to the slide open position automatically (See FIGS. 14, 15, 16).

Since the present embodiment is constructed as described above, as compared to the above-described conventional example, the pitch between the first connecting member 4 and the second connecting member 6 can be reduced to achieve the compactification of the relative movement urging device S itself easily and surely. Furthermore, the compactification of an electronic device, for example, provided with the relative movement urging device S can be achieved. In addition, the falling of the first connecting member 4 and the second connecting member 6 can be prevented surely, thereby providing smooth, favorable slide condition, and remarkably improving the durability of the first connecting member 4 and the second connecting member 6.

The present embodiment is low in cost and excellent in mass productivity because of its simple structure.

The present embodiment provides excellent productivity, since in its structure the connection of the first connecting member 4 and the second connecting member 6 with respect to the guide member 7 is achieved by merely inserting the slide members 14, 15 of the first connecting member 4 and the second connecting member 6 into the guide holes 12, 13 provided in the guide member 7 to be engaged in a disconnection preventive manner.

Since the present embodiment has a structure in which the guide member 7 is the hollow structure, and the slide structure and the springs 18 for urging the slide structure are housed within the guide member 7, the unexposed springs 18 can prevent adhesion of dust and interference with other parts to improve the durability of the relative movement urging device itself, and furthermore, damage to wiring such as flexible printed circuits placed in the vicinity of the relative movement urging device S can be prevented.

The present embodiment is an extremely efficient structure in that the inside of the guide member 7 functions as the receiver of the springs 18 and guides, and that the first connecting member 4 and the second connecting member 6 function as the guides for the slide sections 14, 15, respectively.

The present embodiment employs the slide structure 3 which slides the overlaying section 2 with respect to the main unit section 1 along the overlaying surface as the connecting section (the relative movement structure 3) of the first member 1 and the second member 2 for providing the relative movement urging device S, but may employ a pivot structure which allows the overlaying section 2 to pivot relatively with respect to the main unit section 1 substantially in parallel with the overlaying surface.

Specifically, the present embodiment employs a pivot structure 3B which is incorporated in either the upper position or the lower position of the slide structure 3A described above as a pivot structure, and the pivot structure 3B is provided with the above-described relative movement urging device S. The relative movement structure of the main unit section 1 and the overlaying section 2 which consists of only the pivot structure 3B and is not provided with the slide structure 3A may be provided with the relative movement urging device S of the present embodiment.

The pivot structure 3B allows the overlaying section 2 to pivot relatively with respect to the main unit section 1 from an overlaying parallel position to an overlaying crossing maximum pivot position substantially in parallel with the overlaying surface. The pivot structure 3B is provided with a pivot urging mechanism (the relative movement urging device S) which produces backward pivot for allowing the overlaying section 2 to pivot backward with respect to the main unit section 1 to the overlaying parallel position until the overlaying section 2 is pivoted with respect to the main unit section 1 by a predetermined angle, and produces, on the contrary, forward urging for forward urging to the overlaying crossing maximum pivot position when the overlaying section 2 is pivoted by the predetermined angle. The pivot angle at which the forward urging is produced is set to be a small angle of 45 degrees or less.

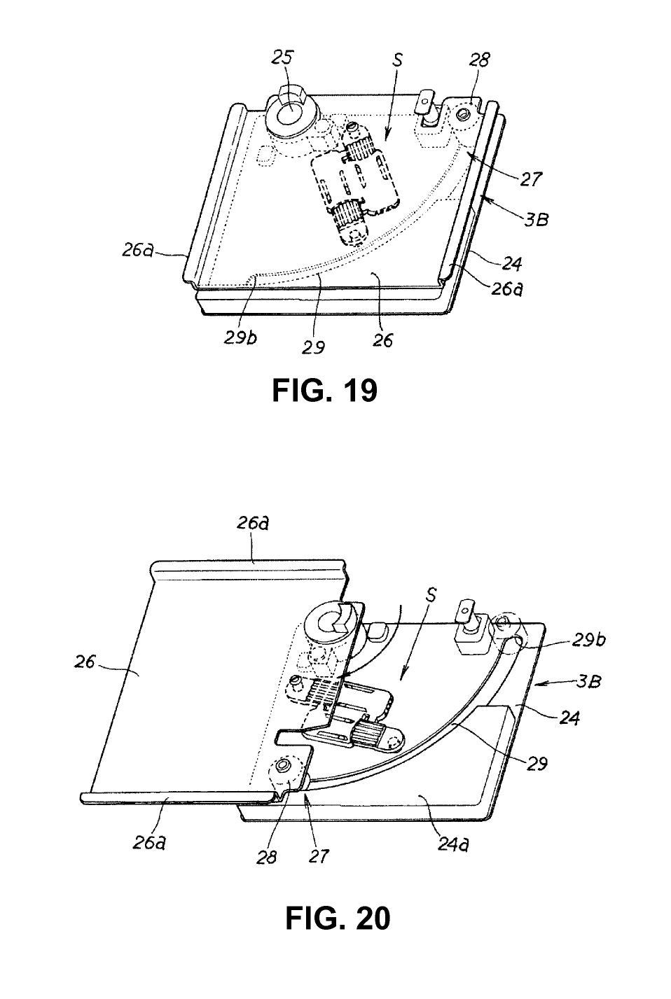

The pivot structure 3B is, as shown in FIGS. 19, 20, includes a first member 24 connected to the main unit section 1 and a second member 26 which is pivotally connected to the first member 24 through a shaft section 25 and is connected to the overlaying section 2.

The present embodiment employs an equivalent to the guide member 19 of the above-described slide structure 3A as the second member 26. The second member 26 is provided with a bearing hole as a bearing section, and the shaft section 25 which is pivotally engaged with the bearing hole is provided on the first member 24 connected to the main unit section 1. The reference numeral 26a is an equivalent to the guide section for guiding the slide member 20 of the slide structure 3A.

Specifically, the shaft section 25 provided on the first member 24 is engaged with the bearing hole of the second member 26 to pivotally engage the second member 26 with the first member 24. A spacer 24a for keeping a space for interposing an urging member and the above-described relative movement urging device S are interposed between the first member 24 and the second member 26 to connect the second member 26 pivotally with respect to the first member 24.

The pivot structure 3B is constructed by providing the second member 26 provided in the overlaying section 2 (or the main unit section 1) pivotally in the slide structure 3A provided between the overlaying section 2 and the main unit section 1, and is provided with a pivot limiting mechanism 27 which is engaged in a hitting manner along with the pivot of the second member 26 and thereby limits the pivot of the overlaying section 2 with respect to the main unit section 1 from the overlaying parallel position to the overlaying crossing maximum pivot position.

The pivot limiting mechanism 27 is, as shown in FIGS. 19, 20, constructed by providing a stopper receiving section 29 (or a stopper section) on the first member 24, with which a stopper section 28 (or the stopper receiving section) provided on the second member 26 is engaged in a hitting manner along with the pivot of the overlaying section 2 with respect to the main unit section 1.

Specifically, the stopper receiving section 29 formed of a curved recessed section (a curved recessed streak), is provided at a predetermined position on the surface of the first member 24. The stopper section 28 which moves (slides) within the stopper receiving section 29 and hits along with the pivot of the second member 26 with respect to the first member 24 is provided on the second member 26. The pivot limiting mechanism 27 is provided to achieve excessive pivot exceeding 90 degrees and unidirectional reciprocal pivot in the second member 26. The pivot limiting mechanism 27 of the present embodiment functions through the engagement between one stopper receiving section 29a and the stopper section 28 at the position at which the overlaying section 2 is in overlaying parallel with the main unit section 1, and functions through the engagement between the other stopper receiving section 29b and the stopper section 28 at the overlaying crossing maximum pivot position.

The pivot structure 3B having the above-described structure is provided with the relative movement urging device S.

The relative movement urging device S is provided in the pivot structure 3B so that backward pivot urging is produced for allowing the overlaying section 2 to pivot backward to the position at which it is in overlaying parallel with the main unit section 1 until the overlaying section 2 is pivoted with respect to the main unit section 1 by a predetermined angle, and forward urging is, on the contrary, produced for backward pivot to the overlaying crossing maximum pivot position when the overlaying section 2 is pivoted by the predetermined angle. When the overlaying section 2 is pivoted from the overlaying parallel position to the overlaying crossing position by the predetermined angle, forward urging is produced. The pivot angle at the overlaying crossing position from the overlaying parallel position is set to be a small angle of 45 degrees or less (about 40 degrees). The angle from the overlaying parallel position to the overlaying crossing position may be set appropriately.

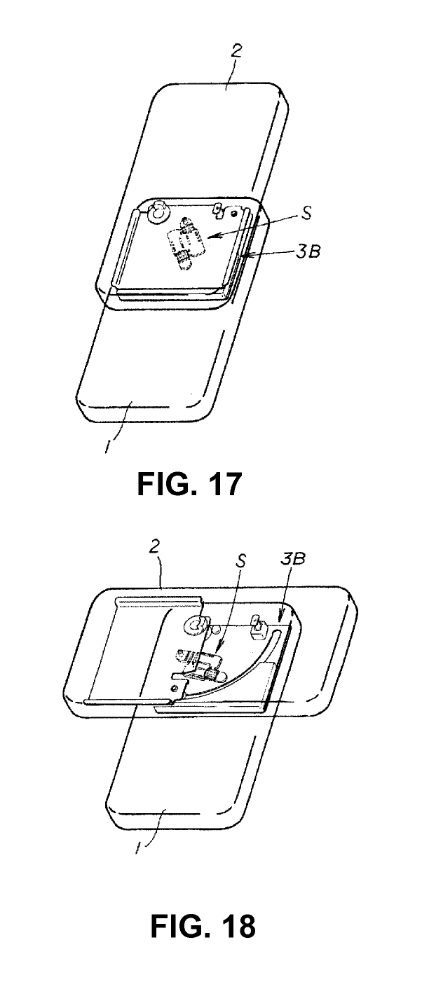

The relative movement urging device S pivotally connects its one end (the first connecting member 4) to the main unit section 1 (the first member 24) and pivotally connects the other end (the second connecting member 6) to the slide structure 3A (the second member 26 as the guide member) provided between the overlaying section 2 and the main unit section 1. Until the overlaying section 2 is pivoted with respect to the main unit section 1 by a predetermined angle, backward urging is produced for allowing the overlaying section to pivot backward in the closing direction. When the overlaying section 2 is pivoted by the predetermined angle, forward urging is, on the contrary, produced for allowing it to pivot forward in the opening direction (see FIGS. 17, 18). In FIGS. 17, 18, the slide structure 3A is not shown.

With the first connecting member 4 and the second connecting member 6 of the relative movement urging device S mutually closed and pressed, one of the first connecting member 4 and the second connecting member 6 is connected to the mounting section of the main unit section 1 (the first member 24), and the other thereof is connected to the mounting section of the slide structure 3A (the second member 26 as the guide member), thereby providing the relative movement urging device S with angle increasing urging which moves the first connecting member 4 and the second connecting member 6 away from each other. With the position at which an angle increasing urging force occurring in the first connecting member 4 and the second connecting member 6 does not work as a pivot force (the overlaying crossing position) as a border, while the overlaying section 2 is slid with respect to the main unit section 1 until the overlaying crossing position, backward pivot urging is produced in the overlaying section 2 through the angle increasing urging. When it is pivoted to a position over the overlaying crossing position, forward urging is produced in the overlaying section 2 through the angle increasing urging.

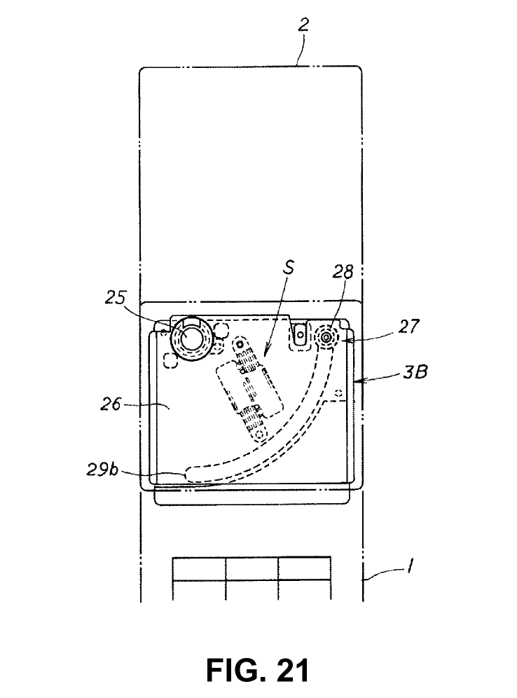

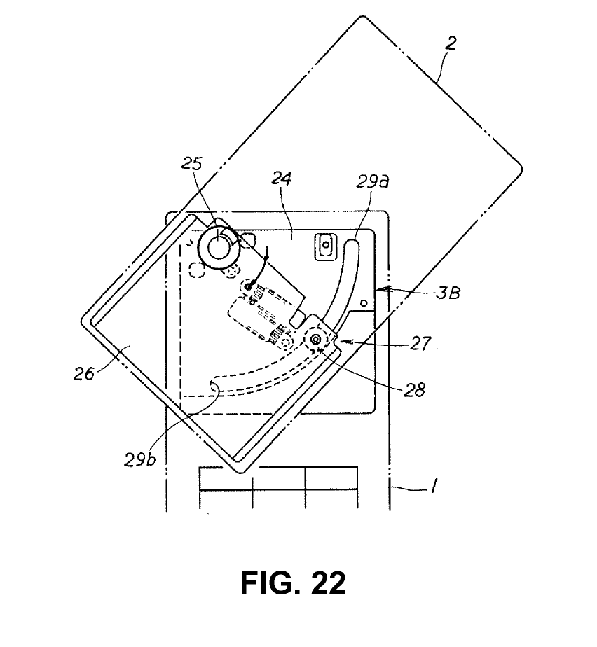

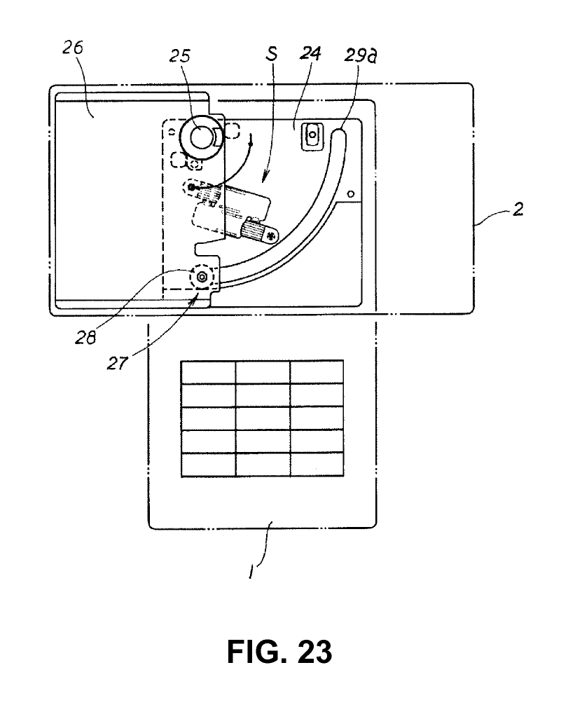

In the present embodiment, with the main unit section 1 fixed as shown in FIG. 21 (the overlaying parallel position), when the overlaying section 2 is pivoted relatively with respect thereto in parallel with the overlaying surface, while the overlaying section 2 is pivoted to the position at which the positions of the first connecting member 4 and the second connecting member 6 of the relative movement urging device S are substantially in alignment with the shaft section 25 as shown in FIG. 22, the angle increasing urging force of the first connecting member 4 and the second connecting member 6 allows the overlaying section 2 to pivot backward with respect to the main unit section 1 to produce backward pivot urging. When the overlaying section 2 is pivoted over the predetermined pivot position, at which the positions of the first connecting member 4 and the second connecting member 6 are not in alignment with the shaft section 25, the angle increasing urging force of the first connecting member 4 and the second connecting member 6 is, on the contrary, produced in the direction allowing the overlaying section 2 to pivot forward further with respect to the main unit section 1, producing forward pivot urging until the overlaying crossing maximum pivot position.

In the pivot structure 3B pivotally overlaying the main unit section 1 and the overlaying section 2, pivot urging is achieved by a simple structure, and pivot with a predetermined angle produces, on the contrary, forward pivot urging in the opening direction automatically. The pivot operation can be lightened, and the overlaying section 2 can be automatically pivoted even freehand, depending on design. It can be designed so that the overlaying section 2 does not become unstable while it pivots by producing both the forward pivot urging and the backward pivot urging in each range, respectively.

A vertically oriented display section, which is long in the slide direction, is provided on the upper side of the overlaying section 2 (the second member) which is overlaid on the main unit section 1 (the first member), and when a horizontally oriented image such as TV and movie, the display section can be switched to a horizontally oriented display, which is long in the orthogonal direction. When the overlaying section 2 provided with the display section on the upper side thereof is pivoted to 90 degrees with respect to the main unit section 1 through the pivot structure 3B in particular, it is pivoted to 90 degrees with the intermediate point of the overlaying section 2 or the display section as the pivot fulcrum (with the shaft section 25, which has relatively moved to the intermediate position by the slide, as the fulcrum), providing the main unit section 1 and the overlaying section 2 with a T-shape rather than an L-shape.

Since the relative movement urging device S is thin and compact, the present embodiment is effective in particular when it is provided in a thick, layered structure when, for example, the pivot structure 3B is incorporated into the slide structure 3A. The present invention is not limited to the present embodiment, and the specific components of each element may be designed appropriately.

What is claimed is:

1. A relative movement urging device for urging relative movement of a first member and a second member which are connected in a relatively movable manner, comprising:
a first connecting member connected to the first member;
a second connecting member which is movable in the departing direction with respect to the first connecting member and is connected to the second member; and
a guide member to which the first connecting member and the second connecting member are slidably connected with urging in the mutually departing direction,
wherein the guide member includes a first guide section which guides slide of the first connecting member and a second guide section which is in parallel with a side of the first guide section to guide the slide of the second connecting member, and
the guide member is formed in a shape in which each basal end of the first guide section and the second guide section becomes a protruded basal end which extends backward over a distal end of the other guide section.

2. A relative movement urging device for urging relative movement of a first member and a second member which are connected in a relatively movable manner, comprising:
a first connecting member connected to the first member;
a second connecting member which is movable in the departing direction with respect to the first connecting member and is connected to the second member; and
a guide member to which the first connecting member and the second connecting member are slidably connected with urging in the mutually departing direction,
wherein the guide member includes a first guide section which guides sliding of the first connecting member and a second guide section which is in parallel with a side of the first guide section to guide the slide of the second connecting member,
the guide member is formed in a shape in which each basal end of the first guide section and the second guide section becomes a protruded basal end which extends backward over a distal end of the other guide section, and
falling prevention sections are provided for supporting and preventing falling of the first connecting member and the second connecting member which slide in the mutually departing direction while protruding from the distal end of the first guide section and the second guide section, respectively, inside the protruded basal ends of the first guide section and the second guide section, respectively.

3. The relative movement urging device according to claim 1,
wherein the guide member is formed in a shape in which each basal end of the first guide section and the second guide section becomes a protruded basal end which extends backward over the distal end of the other guide section by allowing the first guide section and the second guide section having the same or substantially the same length to be arranged in parallel with distal end parts thereof connected, not with basal end parts thereof connected in facing side parts, or inner side parts thereof.

4. The relative movement urging device according to claim 2,
wherein the guide member is formed in a shape in which each basal end of the first guide section and the second guide section becomes a protruded basal end which extends backward over the distal end of the other guide section by allowing the first guide section and the second guide section having the same or substantially the same length to be arranged in parallel with distal end parts thereof connected, not with basal end parts thereof connected in facing side parts, or inner side parts thereof.

5. The relative movement urging device according to claim 1,
wherein the guide member includes a first hollow guide section having guide holes in the internal longitudinal direction and a second hollow guide section which is in parallel with the side of the first guide section and has guide holes in the internal longitudinal direction, which are formed integrally,
the first connecting member and the second connecting member are provided with long slide sections which are slidably inserted into the guide holes which open at the distal ends of the first guide section and the second guide section, respectively, and
the slide sections are provided with disconnection preventive engagement sections which are engaged with engagement sections provided in the guide holes in a disconnection preventive manner when the slide sections are inserted into distal end openings of the guide holes.

6. The relative movement urging device according to claim 2,
wherein the guide member includes a first hollow guide section having guide holes in the internal longitudinal direction and a second hollow guide section which is in parallel with the side of the first guide section and has guide holes in the internal longitudinal direction, which are formed integrally,
the first connecting member and the second connecting member are provided with long slide sections which are slidably inserted into the guide holes which open at the distal ends of the first guide section and the second guide section, respectively, and
the slide sections are provided with disconnection preventive engagement sections which are engaged with engagement sections provided in the guide holes in a disconnection preventive manner when the slide sections are inserted into distal end openings of the guide holes.

7. The relative movement urging device according to claim 5,
wherein the slide sections are slidably inserted into the guide holes against backward urging of springs fit on the slide sections, and
the backward urging of the springs is an urging force for urging the first connecting member and the second connecting member in the mutually departing direction.

8. The relative movement urging device according to claim 6,
wherein the slide sections are slidably inserted into the guide holes against backward urging of springs fit on the slide sections, and
the backward urging of the springs is an urging force for urging the first connecting member and the second connecting member in the mutually departing direction.

9. The relative movement urging device according to claim 1,
wherein the first connecting member is connected to the first member and the second connecting member is connected to the second member, and
until the second member is relatively moved with respect to the first member by a predetermined movement range, backward urging is produced for relatively moving the second member in the backward direction, and when the second member is relatively moved with respect to the first member by the predetermined movement range, forward urging is produced for relatively moving the second member in the forward direction.

10. The relative movement urging device according to claim 2,
wherein the first connecting member is connected to the first member and the second connecting member is connected to the second member, and
until the second member is relatively moved with respect to the first member by a predetermined movement range, backward urging is produced for relatively moving the second member in the backward direction, and when the second member is relatively moved with respect to the first member by the predetermined movement range, forward urging is produced for relatively moving the second member in the forward direction.

11. An electronic device, wherein a relative movement structure to which the first member arranging an operation section or the like and the second member arranging a display section or the like are connected in a relatively movable manner is provided with the relative movement urging device according to claim 1.

12. An electronic device, wherein a relative movement structure to which the first member arranging an operation section or the like and the second member arranging a display section or the like are connected in a relatively movable manner is provided with the relative movement urging device according to claim 2.

13. An electronic device, wherein a relative movement structure to which the first member arranging an operation section or the like and the second member which is overlaid on the first member and arranges a display section or the like are connected slidably in the overlaying surface direction is provided with the relative movement urging device according to claim 1.

14. An electronic device, wherein a relative movement structure to which the first member arranging an operation section or the like and the second member which is overlaid on the first member and arranges a display section or the like are connected slidably in the overlaying surface direction is provided with the relative movement urging device according to claim 2.

15. An electronic device, wherein a relative movement structure to which the first member arranging an operation section or the like and the second member which is overlaid on the first member and arranges a display section or the like are relatively pivotally connected substantially in parallel with the overlaying surface is provided with the relative movement urging device according to claim 1.

16. An electronic device, wherein a relative movement structure to which the first member arranging an operation section or the like and the second member which is overlaid on the first member and arranges a display section or the like are relatively pivotally connected substantially in parallel with the overlaying surface is provided with the relative movement urging device according to claim 2.
